(19) United States
(12) Patent Application Publication
(10) Pub. No.: US 2010/0098146 A1
(43) Pub. Date: Apr. 22, 2010

(54) CHANNEL ESTIMATION METHOD AND DEVICE IN WIRELESS COMMUNICATION SYSTEM

(75) Inventors: Sang In KIM, Mungyeong-si (KR); Hyun Seo OH, Daejeon (KR); Hyun Kyun CHOI, Daejeon (KR); Jong-Suk CHAE, Daejeon (KR); Jong-Hyun PARK, Daejeon (KR); Wan Sik CHOI, Daejeon (KR)

Correspondence Address: STAAS & HALSEY LLP, SUITE 700, 1201 NEW YORK AVENUE, N.W., WASHINGTON, DC, 20005, US

(73) Assignee: Electronics and Telecommunications Research Institute, Daejeon (KR)

(21) Appl. No.: 12/645,518

(22) Filed: Dec. 23, 2009

Related U.S. Application Data
(60) Provisional application No. 61/142,749, filed on Jan. 6, 2009.

(30) Foreign Application Priority Data
Dec. 3, 2007 (KR) 10-2007-0124538
Mar. 5, 2008 (KR) 10-2008-0020670

(51) Int. Cl. H03D 1/04; H03K 5/159; H04L 27/06

(52) U.S. Cl. 375/232; 375/340; 375/346

(57) ABSTRACT

Provided is a channel estimation method and device in a wireless communication system. A channel estimating device for estimating a channel based on a received signal generates an initial channel estimate by using a preamble extracted from the received signal, and determines whether there is a midamble between data symbols appearing next to the preamble. When there is a midamble, the channel estimating device acquires a first channel estimate by using the midamble, and acquires an updated second channel estimate by using the initial channel estimate and the first channel estimate. The channel estimating device performs channel equalization with the second channel estimate to compensate distortion.

### CROSS-REFERENCE TO RELATED APPLICATION

This application claims priority to and the benefit of U.S. patent application Ser. No. 61/142,749 filed in the United States Patent and Trademark Office on Jan. 06, 2009, the entire contents of which are incorporated herein by reference.

### BACKGROUND OF THE INVENTION

(a) Field of the Invention

The present invention relates to a channel estimate method and device in a wireless communication system. Particularly, the present invention relates to a channel estimate method and device in a high mobility environment.

(b) Description of the Related Art

The orthogonal frequency division multiplexing communication (OFDM) system modulates data to be transmitted into a plurality of orthogonal subcarriers, and simultaneously transmits them. Therefore, the OFDM system can prevent multipath interference that deteriorates performance in the receiving mobility environment. However, the OFDM system must perform channel estimation and compensation in order to overcome the Doppler effect occurring when a receiving part moves and weak points occur during data restoration in the multipath channel.

In the conventional channel estimation method, the channel is estimated by assuming that the channel is varied slowly with respect to time or the channel is a time-invariant channel during a single packet. However, the channel is changed with respect to time in the high mobility environment. Also, the size and phase of the OFDM symbol is distorted while passing through the varying channel in the high mobility environment.

Therefore, it is difficult in the channel estimation to compensate the channel of all symbols by using a channel value that is estimated by using a preamble. When the symbol provided next to the preamble and the last symbol have different channel environments, accurate channel compensation of the last symbol is not performed by using the channel estimate that is channel estimated by using the preamble.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a channel estimate method and device for accurately estimating a channel in a high mobility environment.

An exemplary embodiment of the present invention provides a method for estimating a channel based on a received signal in a wireless communication system, including: generating an initial channel estimate by using a preamble extracted from the received signal; determining whether there is a midamble between data symbols that appear consecutive to the preamble; acquiring a first channel estimate by using the midamble when there is a midamble; acquiring an updated second channel estimate by using the initial channel estimate and the first channel estimate; and compensating distortion by performing channel equalization with the second channel estimate.

Another embodiment of the present invention provides a channel estimating device for estimating a channel based on a received signal in a wireless communication system, including: a channel estimator for generating an initial channel estimate by using a preamble extracted from the received signal, acquiring a first channel estimate by using a midamble between data symbols consecutively appearing in the preamble, and acquiring an updated second channel estimate by using the initial channel estimate and the first channel estimate; and an equalizer for compensating distortion by performing channel equalization with the second channel estimate.

### BRIEF DESCRIPTION OF THE DRAWINGS

FIG. 1 shows a configuration of an OFDM system according to an exemplary embodiment of the present invention.

FIG. 2 shows a structure of a transmitted packet according to an exemplary embodiment of the present invention.

FIG. 3 shows a block diagram of a channel estimating method using a preamble according to an exemplary embodiment of the present invention.

FIG. 4 shows a block diagram of a channel estimating method in a time-variant channel environment according to an exemplary embodiment of the present invention.

FIG. 5 shows a flowchart of a channel estimating method according to an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout the specification, unless explicitly described to the contrary, the word “comprise” and variations such as “comprises” or “comprising” will be understood to imply the inclusion of stated elements but not the exclusion of any other elements.

Hereinafter, a channel estimating method and device according to an exemplary embodiment of the present invention will be described in detail with reference to accompanying drawings.

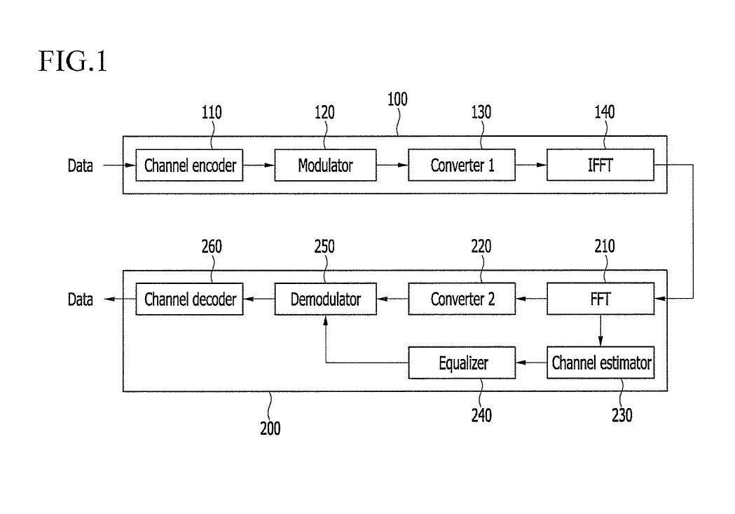

FIG. 1 shows a configuration of an OFDM system according to an exemplary embodiment of the present invention.

As shown in FIG. 1, the OFDM system includes a transmitting device 100 and a receiving device 200.

The transmitting device 100 of includes a channel encoder 110, a modulator 120, a first converter 130, and an inverse fast Fourier transform (IFFT) unit 140.

The channel encoder 110 channel encodes the data to be transmitted, and the modulator 120 modulates the channel encoded data by using the quadrature phase shift keying (QPSK) or quadrature amplitude modulation (QAM) scheme to generate serial data. The first converter 130 converts the generated serial data to parallel data, and the IFFT unit 140 performs an IFFT operation on the parallel data.

The receiving device 200 includes a fast Fourier transform (FFT) unit 210, a second converter 220, a channel estimator 230, an equalizer 240, a demodulator 250, and a channel decoder 260.

The FFT 210 performs an FFT operation on the received data, and the second converter 220 converts the FFT-ed data from the parallel data into serial data. The channel estimator 230 and the equalizer 240 estimate and restore the channel. Also, the demodulator 250 demodulates the received signal, and the channel decoder 260 outputs the original data.

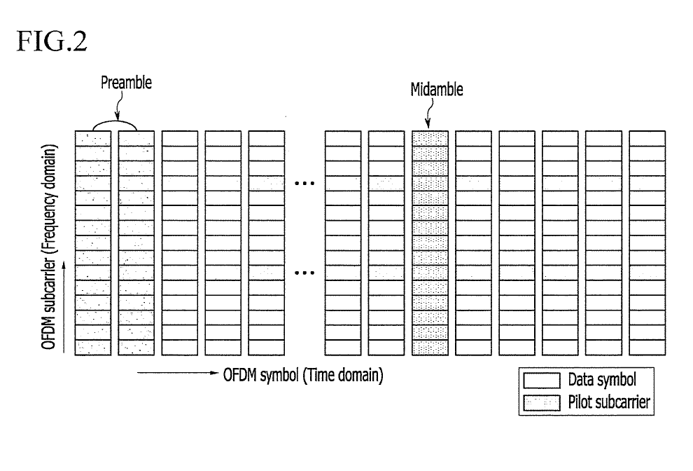

The configuration of the packet transmitted from the transmitting device 100 to the receiving device 200 in the OFDM system according to an exemplary embodiment of the present invention will now be described in detail with reference to FIG. 2.

FIG. 2 shows a structure of a packet according to an exemplary embodiment of the present invention.

As shown in FIG. 2, the vertical axis represents the OFDM subcarrier, and the horizontal axis indicates the OFDM symbol. A single packet starts with reference to two OFDM symbols, and the two OFDM symbols are referred to as a preamble. A data symbol is provided next to the preamble, and includes a pilot subcarrier.

In the packet configuration, a midamble is inserted between the data symbols. Here, the midamble functions in a like manner of the preamble so as to transmit data in the time-variant channel environment.

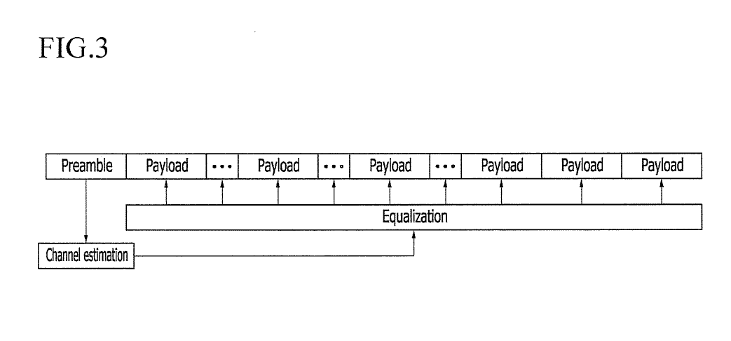

A channel estimation method using a preamble in the single packet configuration will now be described with reference to FIG. 3.

FIG. 3 shows a block diagram of a channel estimating method using a preamble according to an exemplary embodiment of the present invention.

It will be assumed in the preamble using channel estimation method that the channel is not changed during a single packet.

The OFDM system estimates the changes undergone by the packet passing through the channel by using the preamble, and compensates the channel by equalizing the data symbol with the channel estimate.

A channel estimation method using a midamble in the time-variant channel environment will now be described.

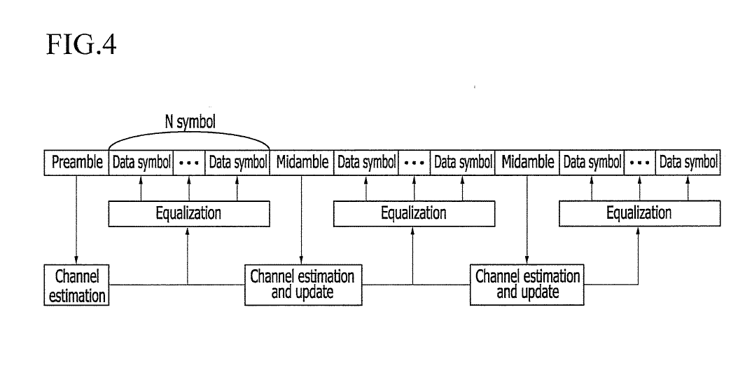

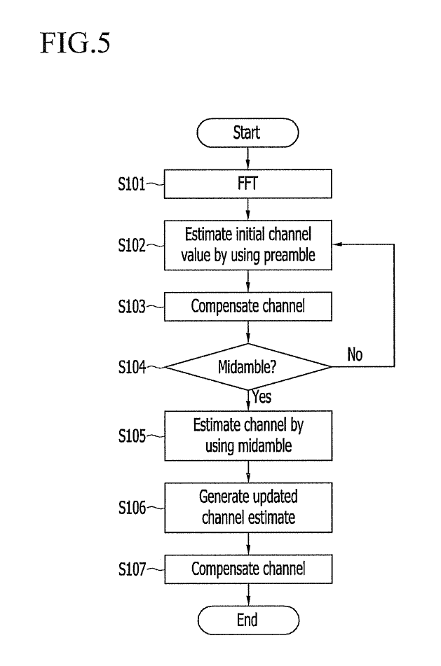

FIG. 4 shows a block diagram of a channel estimating method in a time-variant channel environment according to an exemplary embodiment of the present invention, and FIG. 5 shows a flowchart of a channel estimating method according to an exemplary embodiment of the present invention.

As shown in FIG. 4, at least one midamble is inserted between the data symbols provided after the preamble in the packet configuration.

The OFDM system estimates the change by using the preamble when the packet passes through the initial channel, and compensates the channel by equalizing the data symbol with the corresponding initial channel estimate. Also, the OFDM system estimates the change by using the midamble when the packet passes through a channel environment different from the initial channel, acquires an updated channel estimate by using a corresponding first channel estimate and the initial channel estimate, and compensates the channel by performing a channel equalization based on the updated channel estimate.

In detail, the receiving device (200 in FIG. 1) of the OFDM system receives a received signal (yn) corresponding to the packet to which a midamble is inserted from the transmitting device (100 in FIG. 1). Here, the received signal (yn) is expressed in Equation 1.

yn=xn*hn+wn (1)

Here, yn is a received signal, xn is a transmitted signal, hn is a channel impulse response, and wn is a noise signal.

As shown in FIG. 5, the receiving device 200 performs a fast Fourier transform (FFT) operation on the received signal (yn) to output an FFT-ed signal Y(k) as expressed in Equation 2 (S101).

Y (k)=FFT{yₙ}, (k)=X(k)H(k)+(k) (2)

The channel estimator (230 in FIG. 1) extracts a preamble from the FFT-ed signal Y(k) and acquires an initial channel estimate H(K) by using the extracted preamble (S102). In this instance, the initial channel estimate (^{Ĥ(k)}) is expressed in Equation 3.

Ĥ(k)=Y(K)|X(K)+W (K)|X(K) (3)

The equalizer 240 equalizes the data symbol with the initial channel estimate to compensate the channel (S103). In this instance, the equalized data symbol (^{\hat{X}(k)}) is expressed in Equation 4.

$$\hat{X} ( k ) = \frac{Y ( K )}{\hat{H}} \qquad ( Equation 4 )$$

Having compensated the channel by using the initial channel estimate, the receiving device 200 determines whether there is a midamble (S104). Here, as shown in FIG. 4, the midamble is inserted between the data symbols that are consecutively after the preamble in the single packet configuration.

When there is a midamble, the channel estimator 230 acquires a new channel estimate by using the midamble (S105). When there is no midamble, the equalizer 240 compensates the channel by equalizing the data symbols until a midamble appears.

The channel environment of the OFDM symbol corresponding to the initial channel estimate acquired in S102 is different from the channel environment of the OFDM symbol corresponding to the channel estimate that is newly acquired by using the midamble. Accordingly, in the channel estimation method according to the exemplary embodiment of the present invention, when a midamble appears, the channel is estimated to generate an updated channel estimate, and channel estimation and compensation are performed to process the channel environment.

The channel estimator 230 accumulates the newly acquired channel estimate and the initial channel estimate to generate the average of the channel estimates to be an updated channel estimate (S106).

The equalizer 240 compensates the channel by equalizing the data symbol with the updated channel estimate (S107). The demodulator 250 demodulates the channel compensated data symbol.

Therefore, the distortion of size and phase undergone by the OFDM symbol passing through the channel can be easily compensated when the channel environments of the initial OFDM symbol and the last OFDM symbol are different.

According to an embodiment of the present invention, the channel is estimated by using a midamble, and the distortion of size and phase generated by a predetermined symbol passing through the channel can be compensated based on the estimation in the wireless communication system. As a result, efficient and accurate channel estimation is allowable in a high mobility environment.

The above-described embodiments can be realized through a program for realizing functions corresponding to the configuration of the embodiments or a recording medium for recording the program in addition to through the above-described device and/or method, which is easily realized by a person skilled in the art.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for estimating a channel based on a received signal in a wireless communication system, comprising:
generating an initial channel estimate by using a preamble extracted from the received signal;
determining whether there is a midamble between data symbols that appear consecutive to the preamble;
acquiring a first channel estimate by using the midamble when there is a midamble;
acquiring an updated second channel estimate by using the initial channel estimate and the first channel estimate; and
compensating distortion by performing channel equalization with the second channel estimate.

2. The method of claim 1, wherein
when there is no midamble, compensating distortion by performing channel equalization with the initial channel estimate.

3. The method of claim 1, wherein
the acquiring of a first channel estimate includes accumulating acquired first channel estimates while repeatedly acquiring first channel estimates according to the midamble appearing between the data symbols.

4. The method of claim 3, wherein
the acquiring of a second channel estimate includes:
calculating an average of the accumulated first channel estimates and the initial channel estimate; and
generating the average to be the updated second channel estimate.

5. A channel estimating device for estimating a channel based on a received signal in a wireless communication system, comprising:
a channel estimator for generating an initial channel estimate by using a preamble extracted from the received signal, acquiring a first channel estimate by using a midamble between data symbols consecutively appearing in the preamble, and acquiring an updated second channel estimate by using the initial channel estimate and the first channel estimate; and
an equalizer for compensating distortion by performing channel equalization with the second channel estimate.

6. The channel estimating device of claim 5, wherein
the equalizer compensates distortion by performing channel equalization with the initial channel estimate when there is no midamble between the data symbols consecutively appearing in the preamble.

7. The channel estimating device of claim 5, wherein
the channel estimator accumulates an acquired first channel estimate while repeatedly acquiring first channel estimates according to the midamble appearing between the data symbols.

8. The channel estimating device of claim 7, wherein
the channel estimator calculates an average of the accumulated first channel estimates and the initial channel estimate to generates the average to be the updated second channel estimate.
